(19) United States
(12) Patent Application Publication
(10) Pub. No.: US 2019/0157586 A1
(43) Pub. Date: May 23, 2019

(54) FLEXIBLE DISPLAY PANEL, PRODUCTION METHOD THEREOF AND DISPLAY APPARATUS

(71) Applicant: BOE TECHNOLOGY GROUP CO., LTD., Beijing (CN)

(72) Inventors: Lu Liu, Beijing (CN); Shuang Du, Beijing (CN); Hong Li, Beijing (CN); Jianwei Li, Beijing (CN); Peng Cai, Beijing (CN); Dejun Bu, Beijing (CN); Wenwen Sun, Beijing (CN); Pao Ming Tsai, Beijing (CN)

(21) Appl. No.: 15/989,002

(22) Filed: May 24, 2018

(30) Foreign Application Priority Data
Nov. 21, 2017 (CN) 201711166765.2

(51) Int. Cl. H01L 51/00; H01L 51/56

(52) U.S. Cl. CPC H01L 51/0097; H01L 2251/5338; H01L 51/56

(57) ABSTRACT

This disclosure provides a flexible display panel and a production method thereof, as well as a display apparatus. The flexible display panel comprises: a flexible substrate; an inorganic film layer formed on the flexible substrate, comprising an encapsulating area and a non-encapsulating area, wherein a plurality of micropores are distributed on the inorganic film layer in the non-encapsulating area, and the micropores have a depth greater than or equal to a thickness of the inorganic film layer in the non-encapsulating area.

### CROSS-REFERENCE TO RELATED APPLICATION

This application claims the priority of Chinese Patent Application No. 201711166765.2 filed on Nov. 21, 2017, the contents of which are incorporated hereby as a part of this application by reference in its entirety.

### BACKGROUND

This disclosure relates generally to the technical field of displays, and more particularly to a flexible display panel, a production method thereof, and a display apparatus.

With the development of display techniques, flexible displays have been more and more widely used. The production of a flexible display panel mainly comprises forming a display device on a flexible substrate, and performing thin film encapsulation on the display device. After the encapsulation process, a laser cutting treatment is further required to be performed at the edge of the flexible display panel.

### SUMMARY

This disclosure provides a flexible display panel and a production method thereof, as well as a display apparatus.

Specifically, this disclosure provides a flexible display panel, comprising a flexible substrate, and an inorganic film layer formed on the flexible substrate. The inorganic film layer comprises an encapsulating area and a non-encapsulating area. A plurality of micropores are distributed on the inorganic film layer in the non-encapsulating area. These micropores have a depth greater than or equal to a thickness of the inorganic film layer in the non-encapsulating area.

In some embodiments, a difference between the depth of the micropores and the thickness of the inorganic film layer in the non-encapsulating area is less than or equal to 1 μm.

In some embodiments, the micropores have a diameter of 1 μm-3 μm.

In some embodiments, a distance between any two adjacent micropores is 1 μm-5 μm.

In some embodiments, the micropores have a shape of any one of a circle, a triangle, a quadrangle, a pentagon, a hexagon, and a pentagram.

In some embodiments, a distribution pattern of the micropores in the non-encapsulating area is any one of a circle, a triangle, a quadrangle, a pentagon, and a hexagon.

In some embodiments, the flexible substrate comprises a polyimide substrate.

Furthermore, this disclosure further provides a production method of a flexible display panel, comprising steps of providing a flexible substrate, forming an inorganic film layer on the flexible substrate, and forming a plurality of micropores on the inorganic film layer. The inorganic film layer comprises an encapsulating area and a non-encapsulating area, and the plurality ofmicropores are formed in the non-encapsulating area. The micropores have a depth greater than or equal to a thickness of the inorganic film layer in the non-encapsulating area.

In some embodiments, the step of forming a plurality of micropores on the inorganic film layer in the non-encapsulating area comprises performing micropore-drilling scanning on the inorganic film layer in the non-encapsulating area with a laser to form a plurality of micropores on the inorganic film layer in the non-encapsulating area.

In some embodiments, a difference between the depth of the micropores and the thickness of the inorganic film layer in the non-encapsulating area is less than or equal to 1 μm.

In some embodiments, the micropores have a diameter of 1 μm-3 μm.

In some embodiments, a distance between any two adjacent micropores is 1 μm-5 μm.

In some embodiments, the micropores have a shape of any one of a circle, a triangle, a quadrangle, a pentagon, a hexagon, and a pentagram.

In some embodiments, a distribution pattern of the micropores in the non-encapsulating area is any one of a circle, a triangle, a quadrangle, a pentagon, and a hexagon.

In some embodiments, the flexible substrate comprises a polyimide substrate.

Additionally, this disclosure further provides a display apparatus comprising a flexible display panel as described above.

### BRIEF DESCRIPTION OF THE DRAWINGS

FIG. 1 shows a sectional schematic diagram of a flexible display panel.

FIG. 2 shows a sectional schematic diagram of another flexible display panel.

FIG. 3 shows a sectional schematic diagram of a flexible display panel in an embodiment of this disclosure.

FIG. 4 shows a schematic plan view of a flexible display panel in an embodiment of this disclosure.

FIG. 5 shows a flow chart of a production method of a flexible display panel in an embodiment of this disclosure.

### DETAILED DESCRIPTION

In order to enable the objects, features, and advantages of this disclosure described above to be more clearly and easily to be understood, this disclosure will be further illustrated in detail below in conjunction with accompanying drawings and specific embodiments.

In the production process of a flexible display panel, when a laser cutting treatment is performed at the edge of the flexible display panel and an inorganic film layer is laser-cut, cracks of the inorganic film layer will be generated, leading to failure of the encapsulation of a display device when the cracks are conducted to an encapsulating area. In order to prevent the generation of cutting cracks, the place of cutting may be designed to be a plurality of cutting slits; otherwise, the inorganic film layer at the place of cutting are completely etched off.

However, when cutting locations are designed to be a plurality of cutting slits in order to prevent the generation of cutting cracks, the width occupied by the cutting slits will lead to the increase in the width of the border of the flexible display panel. When the inorganic film layer is completely etched off at the place of cutting, warping or curling of the film layer at the edge will occur due to the absence of dragging effect of film layers at the edge position after cutting, leading to failure of encapsulation.

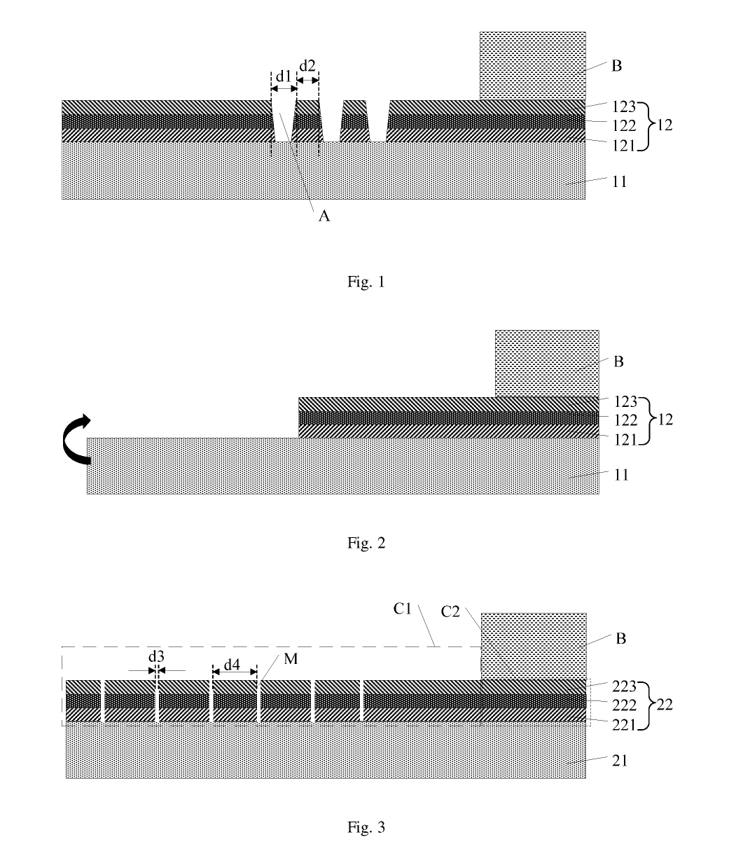

In the structure of the flexible display panel, as shown in FIG. 1, the place of cutting is designed to be a plurality of cutting slits A wherein the number of the cutting slits is typically 3-5, the width of the cutting slit A is d1, the distance between two adjacent cutting slits A is d2, and the total width occupied by all of the cutting slits and distances therebetween is 30-100 leading to the increase in the width of the border of the flexible display panel. Furthermore, as shown in FIG. 2, when the inorganic film layer 12 is completely etched off at the cutting location, warping or curling of the film layer at the edge will occur due to the absence of dragging effect of film layers at the edge position after cutting. Here, the inorganic film layer 12 comprises a first inorganic film layer 121, a second inorganic film layer 122, and a third inorganic film layer 123, 11 is a flexible substrate, and B is a display device after thin film encapsulation.

With respect to the problems described above, an embodiment of this disclosure provides a flexible display panel, which can reduce the width of the border of the flexible display panel and prevent warping or curling of the film layer at the edge.

FIG. 3 provides a sectional schematic diagram of a flexible display panel in an embodiment of this disclosure. An embodiment of this disclosure provides a flexible display panel, comprising a flexible substrate 21 and an inorganic film layer 22 formed on the flexible substrate 21, comprising an encapsulating area C2 and a non-encapsulating area C1. A plurality of micropores M are distributed on the inorganic film layer 22 in the non-encapsulating area C1, and the depth of the micropore M is greater than or equal to the thickness of the inorganic film layer 22 in the non-encapsulating area C1. That is, the micropore may be a through hole which exactly penetrates the inorganic film layer 22 wherein the depth of the micropore M is equal to the thickness of the inorganic film layer 22 in the non-encapsulating area C1, or may be composed of two parts wherein one part is a through hole penetrating the inorganic film layer 22 and the other part is a blind hole located in the flexible substrate 21.

The depth of the micropore M is designed to be greater than or equal to the thickness of the inorganic film layer 22 in the non-encapsulating area C1 to ensure that the micropore M can completely penetrate the inorganic film layer 22 in the non-encapsulating area C1. When a cutting treatment is performed by using a laser at the edge of the flexible display panel and when the inorganic film layer 22 in the non-encapsulating area C1 is laser-cut, micropores M on the inorganic film layer 22 in the non-encapsulating area C1 may effectively prevent cracks from being conducted to the encapsulating area C2.

A difference between the depth of the micropore M and the thickness of the inorganic film layer 22 in the non-encapsulating area C1 is less than or equal to 1 μm. That is, the depth of the blind hole of the micropore M located in the flexible substrate 21 is less than or equal to 1 μm. This design simultaneously effectively prevents cracks from being conducted to the encapsulating area C2, and prevents damage of the flexible substrate 21 by the micropore M.

The diameter d3 of the micropore M is 1 μm-3 μm, the distance d4 between any two adjacent micropores M is 1 μm-5 μm, and the shape of the micropore M is any one of a circle, a triangle, a quadrangle, a pentagon, a hexagon, and a pentagram. Here, the quadrangle may be any one of a diamond, a rectangle, and a trapezoid.

When the shape of the micropore M is a circle, the diameter of the micropore M is 1 μm-3 μm.

When the shape of the micropore M is a triangle, the diameter of the micropore M is the diameter of the circumscribed circle of the triangle, and the diameter of the micropore M is 1 μm-3 μm.

When the shape of the micropore M is a quadrangle, the diameter of the micropore M is the diameter of the circumscribed circle of the quadrangle, and the diameter of the micropore M is 1 μm-3 μm.

When the shape of the micropore M is a pentagon, the diameter of the micropore M is the diameter of the circumscribed circle of the pentagon, and the diameter of the micropore M is 1 μm-3 μm.

When the shape of the micropore M is a hexagon, the diameter of the micropore M is the diameter of the circumscribed circle of the hexagon, and the diameter of the micropore M is 1 μm-3 μm.

When the shape of the micropore M is a pentagram, the diameter of the micropore M is the diameter of the circumscribed circle of the pentagram, and the diameter of the micropore M is 1 μm-3 μm.

The distribution pattern of the micropores M in the non-encapsulating area C1 is any one of a circle, a triangle, a quadrangle, a pentagon, and a hexagon.

A laser is typically used to perform micropore-drilling scanning on the inorganic film layer 22 in the non-encapsulating area C1 to form micropores M. The penetration depth of the micropore is controlled by adjusting the energy of the laser. When the energy of laser is greater, the penetration depth of the micropore is greater; and when the energy of laser is smaller, the penetration depth of the micropore is smaller. The laser by which micropore penetration is performed on the inorganic film layer 22 in the non-encapsulating area C1 may be an ultrashort pulse laser.

Here, the flexible substrate 21 comprises at least one layer of a polyimide substrate. Particularly, the flexible substrate 21 may be a single-layer PI (polyimide) substrate, may be a double-layer PI substrate, or may be a three-layer PI substrate. This is not limited in embodiments of this disclosure.

8 to 9 inorganic film layers are typically deposited when the display device is produced on the flexible substrate 21. After the production of the display device on the flexible substrate 21 is complete, thin film encapsulation is further required to be performed on the display device to obtain the display device B after thin film encapsulation. The area corresponding to the display device B after the thin film encapsulation on the inorganic film layer 22 may be referred to as encapsulating area C2. When the inorganic film layers are deposited, 3 inorganic film layers 22 are deposited at the edge position of the flexible substrate 21, which are a first inorganic film layer 221, a second inorganic film layer 222, and a third inorganic film layer 223, respectively. Here, the material of the inorganic film layer 22 is typically silicon nitride or silicon oxide.

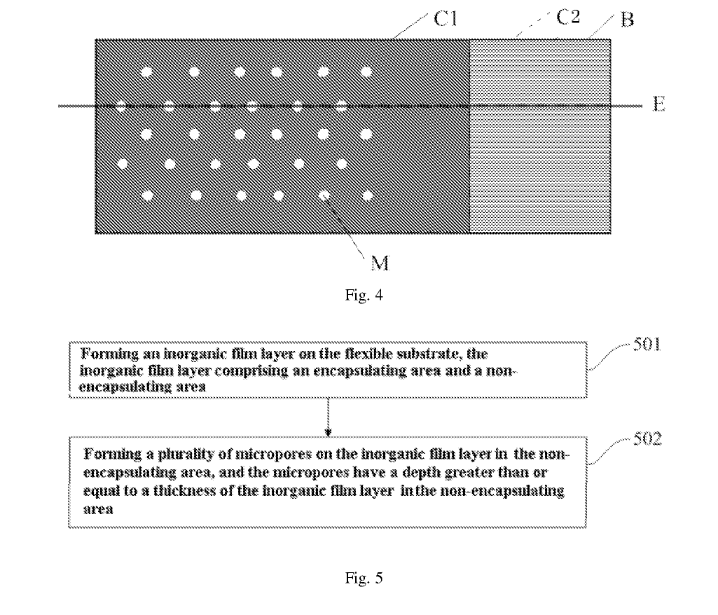

With reference to FIG. 4, there is shown a schematic plan view of a flexible display panel in an embodiment of this disclosure.

The flexible display panel in the embodiment of this disclosure comprises a flexible substrate 21 and an inorganic film layer 22 formed on the flexible substrate 21. The inorganic film layer 22 comprises an encapsulating area C2 and a non-encapsulating area C1. The area corresponding to the display device B after the thin film encapsulation on the inorganic film layer 22 may be referred to as encapsulating area C2.

A plurality of micropores M are distributed on the inorganic film layer 22 in the non-encapsulating area C1. The micropores M may be arranged in the whole surface or may be arranged in areas on the non-encapsulating area C1.

For example, micropores M may be formed on the whole surface on the non-encapsulating area C1, and when the inorganic film layer 22 in the non-encapsulating area C1 is subsequently required to be cut, cutting is performed by a laser according to the requirement for the width of the border of the flexible display panel at a position in the non-encapsulating area C1 where the distance from the encapsulating area C2 is greater than the requirement for the width of the border.

Here, the sectional schematic diagram of the flexible display panel as shown in FIG. 4 along section E is as shown in FIG. 3.

An embodiment of this disclosure further provides a display apparatus, comprising the flexible display panel described above. The flexible display panel comprises: a flexible substrate; an inorganic film layer formed on the flexible substrate, comprising an encapsulating area and a non-encapsulating area, wherein a plurality of micropores are distributed on the inorganic film layer in the non-encapsulating area, and the micropores have a depth greater than or equal to a thickness of the inorganic film layer in the non-encapsulating area.

A difference between the depth of the micropores and the thickness of the inorganic film layer in the non-encapsulating area is less than or equal to 1 μm.

Here, the diameter of the micropore is 1 μm-3 μm. The distance between any two adjacent micropores is 1 μm-5 μm.

The shape of the micropore is any one of a circle, a triangle, a quadrangle, a pentagon, a hexagon, and a pentagram.

The distribution pattern of the micropores in the non-encapsulating area is any one of a circle, a triangle, a quadrangle, a pentagon, and a hexagon.

The flexible substrate comprises at least one layer of a polyimide substrate.

In practical use, the display apparatus in the embodiment of this disclosure may be any product or member with display function, such as a television, a display, a digital camera, a cell phone, a tablet computer, and the like.

In an embodiment of this disclosure, this display apparatus comprises a flexible display panel, wherein an inorganic film layer is formed on a flexible substrate and a plurality of micropores are formed on the inorganic film layer in the non-encapsulating area, the depth of the micropore is greater than or equal to the thickness of the inorganic film layer in the non-encapsulating area. A plurality of micropores are formed on the inorganic film layer in the non-encapsulating area. When cutting treatment is performed by using laser at the edge of the flexible display panel, and when the inorganic film layer in the non-encapsulating area is laser-cut, micropores on the inorganic film layer in the non-encapsulating area may have the effect of preventing the conduction of cracks. Therefore, cracks may be prevented from be conducted to the encapsulating area and the design of cutting slits for preventing the generation of cracks are not required, so as to reduce the width of the border of the flexible display panel. At the meanwhile, the inorganic film layer may have the effect of support to prevent warping or curling of the film layer at the edge.

With reference to FIG. 5, there is shown a flow chart of a production method of a flexible display panel in an embodiment of this disclosure, and it may specifically comprise the steps of:

Step 501, forming an inorganic film layer on the flexible substrate, the inorganic film layer comprising an encapsulating area and a non-encapsulating area; and

Step 502, forming a plurality of micropores on the inorganic film layer in the non-encapsulating area, and the depth of the micropore being greater than or equal to the thickness of the inorganic film layer in the non-encapsulating area.

In an embodiment of this disclosure, as shown in FIG. 3, inorganic film layers are deposited on the flexible substrate 21 to form a display device, and 8 to 9 inorganic film layers are typically deposited. When the inorganic film layers are deposited, 3 inorganic film layers 22 are deposited at the edge position of the flexible substrate 21, which are a first inorganic film layer 221, a second inorganic film layer 222, and a third inorganic film layer 223, respectively.

Here, the inorganic film layer 22 comprises an encapsulating area C2 and a non-encapsulating area C1. After the production of the display device on the flexible substrate 21 is complete, thin film encapsulation is further required to be performed on the display device to obtain the display device B after thin film encapsulation. The area corresponding to the display device B after the thin film encapsulation on the inorganic film layer 22 may be referred to as encapsulating area C2. The non-encapsulating area C1 is located at the edge position of the inorganic film layer 22.

Here, the display device may be specifically an OLED (organic light emitting diode) display device.

In an embodiment of this disclosure, a plurality of micropores M are formed on the inorganic film layer 22 in the non-encapsulating area C1 and the depth of the micropore M is greater than or equal to the thickness of the inorganic film layer 22 in the non-encapsulating area C1 to ensure that the micropore M may completely penetrate the inorganic film layer in the non-encapsulating area C1.

Particularly, micropore-drilling scanning is performed on the inorganic film layer 22 in the non-encapsulating area C1 with a laser to form a plurality of micropores M on the inorganic film layer 22 in the non-encapsulating area C1. Here, the laser by which micropore penetration is performed on the inorganic film layer 22 in the non-encapsulating area C1 may be an ultrashort pulse laser.

It is to be indicated that when a flexible display panel is produced, it is typical to first produce a flexible substrate 21 on a carrier substrate and then further produce a display device on the flexible substrate 21, and thin film encapsulation is performed on the display device. After encapsulation is complete, micropore-drilling scanning is performed on the inorganic film layer 22 in the non-encapsulating area C1 with a laser to form a plurality of micropores M on the inorganic film layer 22 in the non-encapsulating area C1. Next, an LLO (laser lift off) technique is further required to be performed to separate the flexible substrate 21 from the carrier substrate, and cutting treatment is finally performed by a laser at the edge position of the flexible display panel. When the inorganic film layer 22 in the non-encapsulating area C1 is laser-cut, micropores M on the inorganic film layer 22 in the non-encapsulating area C1 may effectively prevent cracks from being conducted to the encapsulating area C2.

In an embodiment of this disclosure, an inorganic film layer is formed on a flexible substrate and a plurality of micropores are formed on the inorganic film layer in the non-encapsulating area, and the depth of the micropore is greater than or equal to the thickness of the inorganic film layer in the non-encapsulating area. A plurality of micropores are formed on the inorganic film layer in the non-encapsulating area. When a cutting treatment is performed by using a laser at the edge of the flexible display panel, and when the inorganic film layer in the non-encapsulating area is laser-cut, micropores on the inorganic film layer in the non-encapsulating area may have the effect of preventing the conduction of cracks. Therefore, cracks may be prevented from be conducted to the encapsulating area and the design of cutting slits for preventing the generation of cracks are not required, so as to reduce the width of the border of the flexible display panel. At the meanwhile, the inorganic film layer may have the effect of support to prevent warping or curling of the film layer at the edge.

Method embodiments described above are expressed as combinations of a series of actions for the purpose of simple description. However, it is to be known by the person skilled in the art that this disclosure is not limited by the order of the actions described, because certain steps may be performed in another order or in parallel according to this disclosure. Next, it is also to be known by the person skilled in the art that the embodiments described in the specification all belong to the preferable embodiments, and the actions and modules involved are not necessarily required by this disclosure.

Various embodiments in this specification are all described in a progressive manner. Each of the embodiments emphatically illustrates those different from other embodiments, and the same or similar parts between embodiments can be referred to each other. Finally, it is to be further indicated that the relational terms such as first, second, and the like are merely to distinguish one entity or operation from another entity or operation, and it does not necessarily require or imply that there is any actual relation or order between these entities and operations. Additionally, terms “include”, “comprise”, or any other variant, intends to cover nonexclusive inclusion, such that a process, method, merchandise, or device comprising a range of elements comprises not only those elements, but also other elements which are not specifically listed or elements intrinsically possessed by this process, method, merchandise, or device. In absence of more limitations, an element defined by a sentence “comprise a” does not exclude that there is additionally the same element in a process, method, merchandise, or device comprising this element.

A flexible display panel, a production method thereof, and a display apparatus provided by this disclosure are introduced in detail above. Principles and embodiments of this disclosure are elaborated herein by using specific embodiments, and the description of the above embodiments is only used to help the understanding of the method of this disclosure and the core idea thereof. At the meanwhile, with respect to those of ordinary skill in the art, modifications will be made to specific embodiments and application ranges according to the idea of this disclosure. In summary, the contents of this specification should not be construed as limiting this disclosure.

1. A flexible display panel comprising:
a flexible substrate;
an inorganic film layer formed on the flexible substrate, and comprising an encapsulating area and a non-encapsulating area,
wherein a plurality of micropores are distributed on the inorganic film layer in the non-encapsulating area, and wherein the micropores have a depth greater than or equal to a thickness of the inorganic film layer in the non-encapsulating area.

2. The flexible display panel according to claim 1, wherein a difference between the depth of the micropores and the thickness of the inorganic film layer in the non-encapsulating area is less than or equal to 1 μm.

3. The flexible display panel according to claim 1, wherein the micropores have a diameter of 1 μm-3 μm.

4. The flexible display panel according to claim 1, wherein a distance between any two adjacent micropores is 1 μm-5 μm.

5. The flexible display panel according to claim 1, wherein the micropores have a shape of any one of a circle, a triangle, a quadrangle, a pentagon, a hexagon, and a pentagram.

6. The flexible display panel according to claim 1, wherein a distribution pattern of the micropores in the non-encapsulating area is any one of a circle, a triangle, a quadrangle, a pentagon, and a hexagon.

7. The flexible display panel according to claim 1, wherein the flexible substrate comprises a polyimide substrate.

8. A production method of a flexible display panel, comprising steps of:
providing a flexible substrate;
forming an inorganic film layer on the flexible substrate, the inorganic film layer comprising an encapsulating area and a non-encapsulating area; and
forming a plurality of micropores on the inorganic film layer in the non-encapsulating area, and the micropores have a depth greater than or equal to a thickness of the inorganic film layer in the non-encapsulating area.

9. The production method according to claim 8, wherein the step of forming a plurality of micropores on the inorganic film layer in the non-encapsulating area comprises:
performing micropore-drilling scanning on the inorganic film layer in the non-encapsulating area with a laser to form a plurality of micropores on the inorganic film layer in the non-encapsulating area.

10. The production method according to claim 8, wherein a difference between the depth of the micropores and the thickness of the inorganic film layer in the non-encapsulating area is less than or equal to 1 μm.

11. The production method according to claim 8, wherein the micropores have a diameter of 1 μm-3 μm.

12. The production method according to claim 8, wherein a distance between any two adjacent micropores is 1 μm-5 μm.

13. The production method according to claim 8, wherein the micropores have a shape of any one of a circle, a triangle, a quadrangle, a pentagon, a hexagon, and a pentagram.

14. The production method according to claim 8, wherein a distribution pattern of the micropores in the non-encapsulating area is any one of a circle, a triangle, a quadrangle, a pentagon, and a hexagon.

15. The production method according to claim 8, wherein the flexible substrate comprises a polyimide substrate.

16. A display apparatus, comprising the flexible display panel according to claim 1.
